(19) United States
(12) Patent Application Publication
(10) Pub. No.: US 2009/0262500 A1
(43) Pub. Date: Oct. 22, 2009

(54) COOLING DEVICE, HEAT SINK, AND ELECTRONIC APPARATUS

(75) Inventors: Takuya Makino, Kanagawa (JP); Hiroshi Takino, Tokyo (JP); Kazuhito Hori, Kanagawa (JP); Hiroichi Ishikawa, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 11/912,538

(22) PCT Filed: Apr. 4, 2006
(86) PCT No.: PCT/JP2006/307103

§ 371 Date: Feb. 4, 2009

(30) Foreign Application Priority Data
Apr. 28, 2005 (JP) 2005-130823
Sep. 5, 2005 (JP) 2005-256935

(51) Int. Cl. H05K 7/20; F28F 7/00; F28D 21/00

(52) U.S. Cl. 361/697; 165/80.3; 165/84

(57) ABSTRACT

There are provided a cooling device and a heat sink that can effectively radiate heat generated by a heat source while reducing the volume of discharged gas to avoid noise, and an electronic apparatus in which the cooling device and the heat sink are mounted. A heat sink 3 includes cutouts 24a and 24b through which air serving as gas can be taken in from the outside and which are provided on a side where air discharged from first and second nozzles 6 and 7 serving as openings of a jet generating mechanism 2 is received. Therefore, the pressure near the cutouts is decreased by air flow discharged from the first and second nozzles 6 and 7, and outside air is taken in through the cutouts 24a and 24b. Consequently, more gas than gas discharged from the first and second nozzles 6 and 7 is discharged from an outlet of the heat sink. This can minimize the volume of jetted gas to avoid noise, and effectively radiate heat generated by a heat source.

### TECHNICAL FIELD

The present invention relates to a cooling device and a heat sink that radiate heat generated from a heat source, and to an electronic apparatus in which the cooling device and the heat sink are mounted.

### BACKGROUND ART

With the increase in performance of PCs (personal computers), the amount of heat generated by a heating element, such as an IC (integrated circuit), has increased. This increase is a problem. Accordingly, various heat radiation techniques have been proposed, or have been commercially available. For example, one heat radiation method is to bring a radiation fin formed of a metal, such as aluminum, into contact with an IC so that heat is transmitted from the IC to the fin. Another heat radiation method is to forcibly remove heated air, for example, in a housing of a PC by means of a fan so that environmental low-temperature air is guided to the surroundings of the heating element. In a further method, both a radiation fin and a fan are used. Heated air around the radiation fin is forcibly removed by the fan while the contact area between the heating element and the air is increased by the radiation fin.

However, in this forced air convection with the fan, a thermal boundary layer is produced on a surface of the radiation fin on a downstream side of the radiation fin, and it is difficult to efficiently take heat away from the radiation fin. In order to solve this problem, for example, the thickness of the thermal boundary layer can be reduced by increasing the velocity of wind from the fan. Unfortunately, when the rotation speed of the fan is increased to increase the wind velocity, noise is produced from a bearing section of the fan, or is produced by wind noise due to the wind from the fan.

In contrast, a method utilizing a vibrating plate that periodically reciprocates is known, which destroys the above-described thermal boundary layer and efficiently takes heat away from a radiation fin without using a fan as an air blowing means (for example, see Japanese Unexamined Patent Application Publication No. 2000-223871 (FIG. 2), Japanese Unexamined Patent Application Publication No. 2000-114760 (FIG. 1), Japanese Unexamined Patent Application Publication No. H2-213200 (FIG. 1), and Japanese Unexamined Patent Application Publication No. H3-116961 (FIG. 3)). These devices include a vibrating plate that substantially and spatially divides the interior of a chamber in two, an elastic member provided in the chamber so as to support the vibrating plate, means for vibrating the vibrating plate, and a plurality of nozzles provided as air intake and outlet ports in the chamber. By causing the vibrating plate to periodically reciprocate using driving means in a direction perpendicular to the vibrating plate, an operation of discharging air in the chamber into the outside air and an operation of taking air into the chamber from the outside are repeated periodically.

For example, when the vibrating plate is displaced upward, the volume of an upper space of the chamber decreases, and therefore, the pressure in the upper space increases. Since the upper space communicates with the outside air via the air intake and outlet ports, air in the upper space is partly discharged to the outside because of the increase in pressure of the upper space. In this case, since the volume of a lower space on a side of the vibrating plate opposite the upper space increases conversely, the pressure in the lower space decreases. Since the lower space communicates with the outside air via the air intake and outlet ports, a part of the outside air near the air intake and outlet ports is drawn into the lower space because of the decrease in pressure of the lower space.

In contrast, when the vibrating plate is displaced downward, the volume of the upper space in the chamber increases, and therefore, the pressure in the upper space decreases. Since the upper space communicates with the outside air via the air intake and outlet ports, a part of the outside air near the air intake and outlet ports is drawn into the upper space because of the decrease in pressure of the upper space. In this case, since the volume of the lower space on the side of the vibrating plate opposite the upper space decreases conversely, the pressure in the lower space increases. Air in the lower space is partly discharged into outside air by the increase in pressure of the lower space. The vibrating plate is driven by, for example, an electromagnetic driving method.

By thus causing the vibrating plate to reciprocate, the operation of discharging air in the chamber into the outside air and the operation of taking the outside air into the chamber are periodically repeated, and a pulsating flow of air induced by the periodical reciprocating motion is blown against the radiation fan and so on. This allows the thermal boundary layer on the surface of the radiation fin to be destroyed efficiently. Consequently, the radiation fin is cooled efficiently.

The amount of generated heat has been steadily increasing because of recent increases in clock speed. Therefore, for example, in order to destroy the thermal boundary layer formed near the radiation fin by heat generation, it is necessary to feed more air to the IC and the radiation fin than before. In the air discharging method utilizing the vibrating plate that periodically reciprocates, as described in Japanese Unexamined Patent Application Publication No. 2000-223871 (FIG. 2), Japanese Unexamined Patent Application Publication No. 2000-114760 (FIG. 1), Japanese Unexamined Patent Application Publication No. H2-213200 (FIG. 1), and Japanese Unexamined Patent Application Publication No. H3-116961 (FIG. 3), the amount of discharged air can be increased by increasing the vibration amplitude of the vibrating plate.

Unfortunately, noise increases as the vibration amplitude of the vibrating plate increases. Practically, it is necessary to operate the vibrating plate with a low amplitude so that noise is negligible. For this reason, the volume of air that can be discharged through the nozzles is limited in the air discharging method utilizing the vibrating plate that periodically reciprocates. Consequently, it is impossible to increase the amount of heat that can be removed.

In view of the above-described circumstances, an object of the present invention is to provide a cooling device and a heat sink that can effectively radiate heat generated by a heat source while reducing the volume of discharged gas to avoid noise, and an electronic apparatus in which the cooling device and the heat sink are mounted.

### DISCLOSURE OF INVENTION

In order to achieve the above object, a cooling device according to a main aspect of the present invention includes a jet generating mechanism and a heat sink. The jet generating mechanism includes a housing having an opening and containing gas, and a vibrating body vibratably mounted in the housing and configured to vibrate to discharge the gas as a pulsating flow through the opening. The heat sink includes a first vent portion through which outside gas can be taken in. The first vent portion is provided on a side of the heat sink where the gas discharged from the opening is received.

According to the present invention, the heat sink includes the first vent portion through which outside gas can be taken in and which is provided on the side where gas discharged from the opening is received. Therefore, the pressure near the first vent portion is decreased by the flow of the gas discharged from the opening, and outside air is taken in through the first vent portion. Consequently, more gas than the gas discharged from the opening is discharged from an outlet of the heat sink.

While the “first vent portion” is, for example, a cutout, it is not limited thereto. The “first vent portion” includes, of course, a hole such as a through hole, and includes all parts that allow outside gas to flow into the heat sink. The number of first vent portions is not limited to one, and a plurality of first vent portions may be provided.

When the heat sink and the jet generating mechanism are combined, for example, gas discharged from the opening intermittently flows in the jet generating mechanism utilizing the vibrating plate that periodically reciprocates. For this reason, after gas is discharged for a certain time, air is taken in through the same opening. In this case, outside gas is drawn into the heat sink by the flow of discharged gas.

When the volume of gas drawn from the outside increases, the volume of gas flowing out from the outlet of the heat sink increases as a result. That is, thermal resistance can be reduced without increasing the volume of gas discharged from the opening.

One method for increasing the volume of gas drawn from the outside is to increase the flow velocity of gas discharged from the opening. However, when the flow velocity of gas discharged from the opening is increased, flow noise depending on the maximum flow velocity of gas discharged from the opening increases. Further, it is necessary to decrease the cross-sectional area of the opening in order to increase the flow velocity of gas discharged from the opening. This increases the pressure loss at the opening such as a nozzle, and thereby increases power consumption of the jet generating mechanism.

Accordingly, in order to easily take in gas from the outside, the first vent portion that can take in gas from the outside is provided on the side of the heat sink where gas discharged from the opening is received. This can easily increase the volume of gas flowing out from the outlet of the heat sink without increasing noise and power consumption, and can effectively radiate heat generated by the heat source.

As a driving method for the vibrating body, for example, electromagnetic action, piezoelectric action, or electrostatic action can be adopted.

While the gas is air as an example, it may be nitrogen, helium gas, argon gas, or other gases.

According to an embodiment of the present invention, the heat sink further includes a radiation plate configured to receive the discharged gas, and the first vent portion is a cutout provided on a side of the radiation plate such as to receive the gas. This facilitates formation, and reduces the production cost. Moreover, gas can be more smoothly drawn in from the outside. For example, when a cutout is provided on the side of the radiation plate such as to receive the gas, the amount of gas flow discharged from the outlet of the heat sink increases by a maximum of approximately 10%.

According to an embodiment of the present invention, the jet generating mechanism further includes a first chamber and a second chamber provided in the housing such that the vibrating body is disposed therebetween. The opening includes a first opening communicating with the first chamber, and a second opening communicating with the second chamber. The heat sink further includes a radiation plate configured to receive the discharged gas, and a partition plate provided on a side of the radiation plate such as to receive the gas and between the first opening and the second opening. The partition plate extends in a direction substantially orthogonal to a straight line that connects the first and second openings.

In the jet generating mechanism using the vibrating plate that periodically reciprocates, for example, gas is alternately discharged from the first opening and the second opening that respectively communicate with the first chamber and the second chamber between which the vibrating plate serving as the vibrating body is disposed. In this case, flow of gas discharged from the first opening sometimes turns toward the second opening that performs gas intake.

In this case, when the vent portion capable of taking in gas from the outside is formed on the side to receive the discharged gas, the degree of turning toward the second opening increases according to the forming manner, and the turned flow may partly come out of the heat sink. For example, when a cutout is provided, this tendency becomes more remarkable as the area of the cutout increases.

Accordingly, in the present invention, the partition plate is provided on a side of the radiation plate such as to receive the gas and between the first opening and the second opening. The partition plate extends in a direction substantially orthogonal to a straight line that connects the first and second openings. Therefore, for example, it is possible to reduce the amount of flow of gas, which is discharged from the first opening and turns toward the second opening that performs gas intake, and to reduce the amount of gas flowing out of the heat sink through the first vent portion. Consequently, more outside gas can be drawn in through the first vent portion, and can flow to the outlet of the heat sink.

For example, when the same volume of gas is discharged from the opening, the amount of flow at the outlet of the heat sink increases by 10 to 30% over the case in which known heat sink and jet generating mechanism are combined. As a result, the amount of flow at the outlet of the heat sink becomes about double the volume of gas discharged from the opening.

That is, by combining the heat sink and the jet generating mechanism according to the present invention, the amount of gas flow at the outlet of the heat sink can be increased without increasing the amount of gas flow discharged from the opening of the jet generating mechanism. Therefore, thermal resistance can be reduced without increasing flow noise that is substantially determined by the maximum flow velocity of gas discharged from the opening.

According to an embodiment of the present invention, the heat sink further includes a radiation plate configured to receive the discharged gas. The radiation plate is formed of a flat plate bent at both sides, and includes a plurality of radiation plates arranged successively. The first vent portion is provided on the bent sides. In this case, a heat sink having a high heat radiation effect can be easily produced by arranging a plurality of radiation plates, and the production cost can be reduced.

For example, when a plurality of radiation plates are successively arranged in a manner such that the bent sides are aligned as upper faces and lower faces, the bent side faces face outside the heat sink. By forming the first vent portion on the bent sides, outside gas can be easily drawn in.

According to an embodiment of the present invention, the radiation plate is formed of a flat plate bent at both sides. The partition plate extends about at the midpoint between the first opening and the second opening, and is inserted in a middle portion between both bent sides of the radiation plate. In this case, even when air intake and air discharging are alternately repeated through the first opening and the second opening, it is possible to more effectively reduce the degree of turning of gas flow toward one of the first and second openings that performs gas intake.

Since the partition plate is inserted in the middle portion between both bent sides of the radiation plate formed of a flat plate, it is easily attached to the radiation plate, and the attachment strength can be increased.

According to an embodiment of the present invention, the partition plate at least overlaps with the first vent portion in plan view. Since gas that is going to flow toward the first vent portion is regulated by the partition plate, the amount of gas turning toward the second opening that performs gas intake can be further reduced, and the amount of gas flowing out of the heat sink through the first vent portion can be reduced further.

According to an embodiment of the present invention, the heat sink includes a second vent portion provided on a side opposite the gas receiving side. While the “second vent portion” is, for example, a cutout, it also includes a hole such as a through hole. The number of second vent portions is not limited to one, and a plurality of second vent portions may be provided.

In this case, pressure loss at the opposite outlet for the inflow gas decreases. Moreover, for example, the amount of gas flowing out of the outlet of the heat sink can be increased, in contrast to the decrease in area of the radiation plate due to the formation of the second vent portion.

According to an embodiment of the present invention, the heat sink further includes a radiation plate configured to receive the discharged gas, and the second vent portion is a cutout provided on the opposite side of the radiation plate. This facilitates formation, and reduces the production cost. Moreover, gas can more smoothly flow outside. For example, when a cutout is provided on the side of the radiation plate opposite the gas receiving side, the amount of gas flowing out of the outlet of the heat sink increases by 3 to 5%.

A heat sink according to another aspect of the present invention receives a pulsating flow of gas via first and second openings of a jet generating mechanism. The jet generating mechanism includes a housing having the first and second openings and containing gas, and a vibrating body vibratably mounted in the housing and configured to vibrate to discharge the pulsating flow of gas via the first and second openings. The heat sink includes a radiation plate having a first vent portion through which outside gas can be taken in, the first vent portion being provided on a gas receiving side where the gas is received, and a partition plate provided on the gas receiving side of the radiation plate and between the first opening and the second opening. The partition plate extends in a direction substantially orthogonal to a straight line that connects the first and second openings.

In the present invention, when gas is received by the radiation plate via the first and second openings of the jet generating mechanism, the partition plate extending in the direction substantially orthogonal to the straight line that connects the first and second openings is provided on the gas receiving side of the radiation plate. Therefore, for example, the amount of flow of gas, which is discharged from the first opening and turns toward the second opening through that performs gas intake, can be reduced, and the amount of gas flowing out of the heat sink from the first vent portion can be reduced. This allows more outside gas to be taken in from the first vent portion and to flow to the outlet of the heat sink. Consequently, the thermal resistance of the heat sink becomes low.

According to an embodiment of the present invention, the first vent portion is a cutout provided on the gas receiving side of the radiation plate. Therefore, formation is facilitated, the production cost can be reduced, and gas can be more smoothly taken in from the outside.

According to an embodiment of the present invention, the radiation plate further includes a second vent portion provided on a side opposite the gas receiving side. In this case, pressure loss is decreased at the opposite outlet for the inflow gas, and the amount of gas flowing out of the outlet of the heat sink can be increased. For example, the increase in radiation efficiency due to the increase in amount of gas flow is larger than the decrease in radiation efficiency due to the decrease in area of the radiation plate caused by forming the second vent portion. Therefore, the radiation efficiency can be increased as a whole.

According to an embodiment of the present invention, the second vent portion is a cutout provided on the opposite side of the radiation plate. In this case, formation is facilitated, and the production cost can be reduced. Moreover, gas can more smoothly flow outside. For example, when a cutout is provided on the side of the radiation plate opposite the gas receiving side, the amount of gas flowing out of the outlet of the heat sink increases by 3 to 5%.

An electronic apparatus according to a further aspect of the present invention includes a heat source; a jet generating mechanism including a housing having an opening and containing gas, and a vibrating body vibratably mounted in the housing and configured to vibrate to discharge the gas as a pulsating flow from the opening; and a heat sink including a radiation plate having a vent portion through which outside gas can be taken in, the vent portion being provided on a gas receiving side where the gas discharged from the opening is received. The heat sink is thermally connected to the heat source. While the “vent portion” is, for example, a cutout, it includes, of course, a hole such as a through hole, and includes all parts that allow outside gas to flow into the heat sink. The number of vent portions is not limited to one, and a plurality of vent portions may be provided.

For example, the electronic apparatus includes a computer (including a laptop or desktop personal computer), a PDA (personal digital assistant), an electronic dictionary, a camera, a display, audio/visual equipment, a mobile phone, a game machine, and other electrical appliances. While the heat source is, for example, an electronic component such as an IC or a resistor, it is satisfactory as long as the heat source can generate heat.

As described above, according to the present invention, it is possible to prevent noise by reducing the volume of discharged gas, and to effectively radiate heat generated by the heat source.

### BRIEF DESCRIPTION OF THE DRAWINGS

FIG. 1 is a perspective view of a cooling device according to a first embodiment.

FIG. 2 is a cross-sectional view, taken along line A-A in FIG. 1.

FIG. 3 is a perspective view of a heat sink according to the first embodiment.

FIG. 4 is a front view of a pressed flat plate before being bent at both sides.

FIG. 5 is a perspective view showing a state in which the flat plate shown in FIG. 4 is bent at both sides by sheet metal working.

FIG. 6 is a perspective view of a heat sink having no cutout.

FIG. 7 is a simulation view showing velocity vectors in the heat sink.

FIG. 8 is a simulation view showing velocity vectors in the heat sink.

FIG. 9 is a perspective view of a heat sink according to a second embodiment.

FIG. 10 is a perspective view showing a state before a partition plate is attached to radiation plates.

FIG. 11 is a simulation view showing velocity vectors in the heat sink.

FIG. 12 is a perspective view of a heat sink according to a third embodiment.

FIG. 13 is a perspective view of a heat sink according to a fourth embodiment.

FIG. 14 is a perspective view of a cooling device according to a fifth embodiment.

FIG. 15 is a perspective view of a heat sink according to a sixth embodiment.

FIG. 16 is a perspective view of the heat sink according to the sixth embodiment in conjunction with heat pipes.

FIG. 17 is a simulation view showing velocity vectors when a cutout is not provided in the sixth embodiment.

FIG. 18 is a simulation view showing velocity vectors when a cutout is provided on the lower side in the sixth embodiment.

FIG. 19 is a partial perspective view of a cooling device according to a seventh embodiment.

FIG. 20 is a partial perspective view of the cooling device, as viewed in a direction opposite the direction adopted in FIG. 19.

FIG. 21 is a cross-sectional view, taken along line J-J in FIG. 20.

FIG. 22 is a partial plan view of the cooling device shown in FIG. 20.

FIG. 23 is a perspective view of a nozzle unit shown in FIG. 19.

### BEST MODE FOR CARRYING OUT THE INVENTION

Embodiments of the present invention will be described below with reference to the drawings.

### First Embodiment

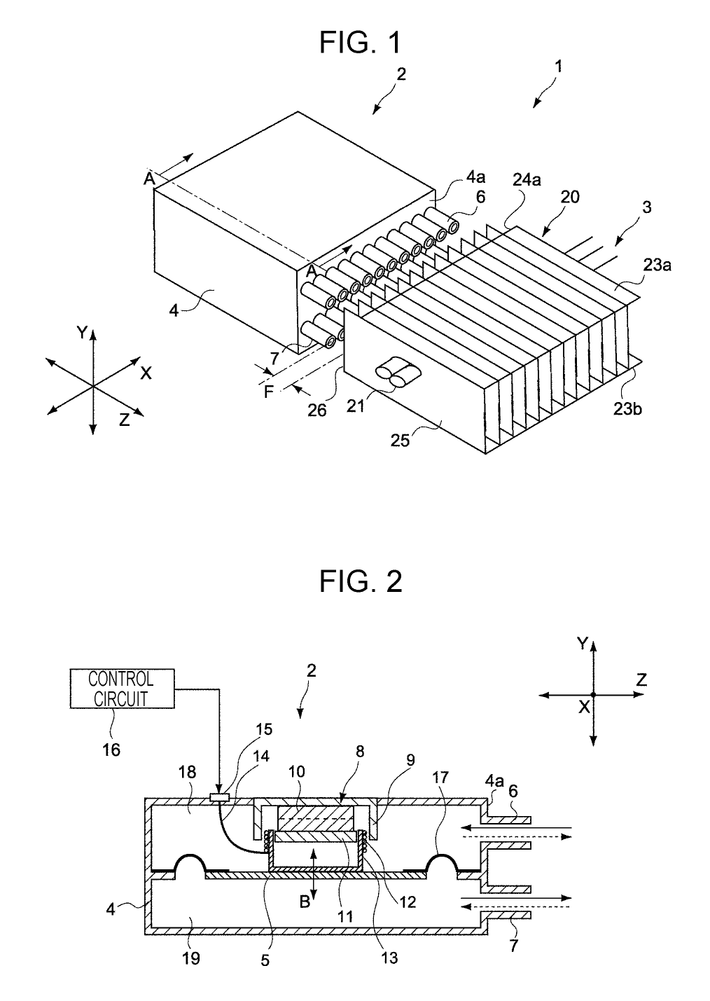

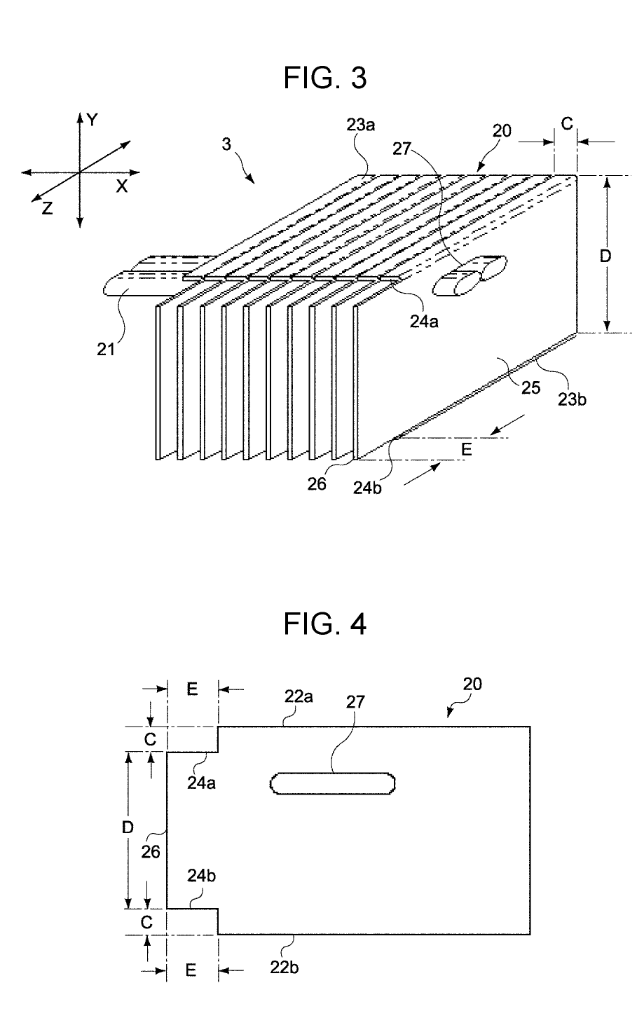

FIG. 1 is a perspective view of a cooling device according to a first embodiment of the present invention, FIG. 2 is a cross-sectional view, taken along line A-A in FIG. 1, and FIG. 3 is a perspective view of a heat sink.

### (Configuration of Cooling Device)

A cooling device 1 includes a jet generating mechanism 2 that discharges a pulsating flow of gas, and a heat sink 3 that receives the gas discharged from the jet generating mechanism 2, for example, as shown in FIG. 1.

The jet generating mechanism 2 includes, for example, a housing 4 containing gas, and a vibrating plate 5 serving as a vibrating body vibratably mounted in the housing.

For example, as shown in FIG. 1, a plurality of first nozzles 6 serving as first openings and a plurality of second nozzles 7 serving as second openings are provided on one side face 4a of the housing 4. The first and second nozzles 6 and 7 discharge air serving as the gas contained in the housing 4 toward the heat sink 3 facing the side face. The first and second nozzles 6 and 7 are arranged in the lateral direction (X-axis direction in FIG. 1). The first and second nozzles 6 and 7 may be provided integrally with the housing 4.

The housing 4 includes an actuator 8 provided between the vibrating plate 5 and an inner wall of the housing 4 so as to drive the vibrating plate 5, for example, as shown in FIG. 2.

For example, in the actuator 8, a magnet 10 magnetized in a vibrating direction B (B in FIG. 2) of the vibrating plate 5 is disposed in a cylindrical yoke 9, and a disc-shaped yoke 11 is attached to the magnet 10, as shown in FIG. 2.

The magnet 10 and the yokes 9 and 11 constitute a magnetic circuit. A coil bobbin 13 on which a coil 12 is wound comes into and out of a space between the magnet 10 and the yoke 9. That is, the actuator 8 serves as a voice coil motor.

A feeder cable 14 is connected to the actuator 8, for example, as shown in FIG. 2. The feeder cable 14 is electrically connected to a control circuit 16, such as a driving IC, via a terminal 15 provided in the housing 4. An electrical signal is supplied from the control circuit 16 to the actuator 8. The yoke 9 and the housing 4 can be formed of the same material or different materials. The coil bobbin 13 is fixed to a surface of the vibrating plate 5. The vibrating plate 5 can be vibrated by this actuator 8 in a direction of arrow B (B in FIG. 2).

The vibrating plate 5 is supported on the inner wall of the housing 4 by an elastic support member 17 so as to divide the interior of the housing in two, for example, as shown in FIG. 2. That is, a first chamber 18 and a second chamber 19 are defined in the housing by the vibrating plate 5, the elastic support member 17, and the housing 4 in a manner such that the vibrating plate 5 is disposed between the first and second chambers 18 and 19.

The housing 4 is formed of, for example, resin, rubber, metal, or ceramic. Resin and rubber are easy to mold and fit for mass production. Moreover, resin and rubber have a high sound attenuation factor, and can reduce noise. In addition, resin and rubber can contribute to weight reduction, and this reduces the cost.

Considering heat radiation from the housing 4, it is desirable that the metal be copper or aluminum having high heat conductivity. The elastic support member 17 is formed of, for example, resin or rubber.

The vibrating plate 5 is formed of, for example, resin, paper, rubber, or metal. The shape of the vibrating plate 5 is not limited to the shape of a flat plate, and may be conical like a vibrating plate mounted in a speaker. Alternatively, the vibrating plate 5 may have a three-dimensional shape.

Operation of the jet generating mechanism 2 having the above-described configuration will be described.

The vibrating plate 5 undergoes sinusoidal oscillation in response to an electrical signal from the control circuit 16, and the volumes of the first and second chambers 18 and 19 are thereby increased or decreased. With the changes in volume of the first and second chambers 18 and 19, the pressures in the first and second chambers 18 and 19 change. Further, with the changes in pressure in the first and second chambers 18 and 19, an air flow is generated via the first and second nozzles 6 and 7.

For example, when the vibrating plate 5 is displaced in a direction such as to increase the volume of the first chamber 18, the internal pressure decreases. This causes outside air to flow into the first chamber 18 through the first nozzle 6. In contrast, when the vibrating plate 5 is displaced in a direction such as to decrease the volume of the first chamber 18, the internal pressure increases. This causes air in the first chamber 18 to be jet outside through the first nozzles 6. This also applies to the second chamber 19. For example, by blowing the discharged air against the heat sink 3, the heat sink 3 can be cooled.

The heat sink 3 includes a plurality of radiation plates 20 that receive air serving as gas discharged from the jet generating mechanism 2, and heat pipes 21 serving as a heat conductive member that transmits heat from a heat source to the radiation plates 20, for example, as shown in FIG. 1.

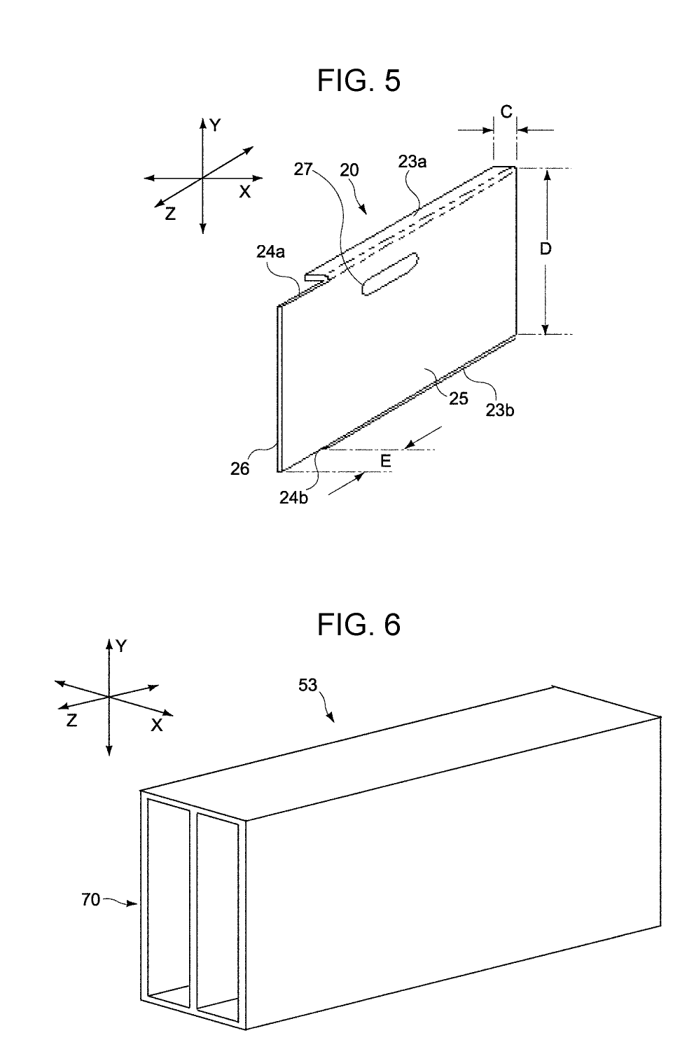

Each radiation plate 20 is formed by a flat plate that has a thickness of approximately 0.3 mm and that is bent in the same direction (X-axis direction in FIG. 5) at positions at a predetermined distance C (C in FIG. 5) from both ends 22a and 22b, for example, as shown in FIG. 5. The predetermined distance is determined by the size of the radiation plate 20. For example, when the length D (D in FIG. 5) of a portion between bent side portions 23a and 23b is 11 mm, the predetermined distance is set at approximately 2.3 mm.

The radiation plate 20 includes cutouts 24a and 24b that are respectively provided as first vent portions (or vent portions) on sides of the bent side portions 23a and 23b where air discharged from the jet generating mechanism 2 is received, for example, as shown in FIGS. 1 and 5.

For example, the cutouts 24a and 24b are formed by cutting out portions of the bent side portions 23a and 23b in a predetermined length E (E in FIG. 5). The cutouts 24a and 24b extend in a gas flowing direction (Z-axis direction in FIG. 5) from an end 26 of the middle portion 25 provided between the bent side portions 23a and 23b where discharged air is received. The cutouts 24a and 24b are substantially rectangular, and, for example, are 4 mm in length.

While only one of the cutouts 24a and 24b can be formed, the amount of gas drawn from the outside becomes less than in a case in which both the cutouts 24a and 24b are provided. The first vent portions are not limited to the cutouts 24a and 24b, and may be through holes. Further, while the cutouts 24a and 24b are respectively provided on the bent side portions 23a and 23b, each of the side portions 23a and 23b can have a plurality of vent portions.

The middle portion 25 of the radiation plate 20 has a substantially elliptical through hole 27 through which two heat pipes 21 can extend, for example, as shown in FIG. 5.

Further, a plurality of radiation plates 20 are successively arranged, for example, as shown in FIG. 3, and surfaces of the bent side portions 23a and 23b of the arranged radiation plates 20 are aligned.

The heat conductive material used for the radiation plates 20 is not limited to a copper alloy, and it is satisfactory as long as the material has a high heat conductivity. For example, an aluminum alloy is frequently used.

Besides the heat pipe, a copper alloy, an aluminum alloy, or a vapor chamber serving as a kind of heat pipe is frequently used as the heat conductive member for transmitting heat from the heat source to the radiation plates 20. Alternatively, a heat transport device utilizing liquid can be used.

A refrigerant, such as pure water, is put in the heat pipes 21. A vapor flow heated by a heat source (not shown) is cooled and liquefied by the radiation plates 20 of the heat sink 3, and is caused by capillary action in the pipes to reflow to the heat source. The use of the heat pipes 21 allows the radiation plates 20 to be disposed apart from the heat source, and also allows the entire electronic apparatus to be thin like a notebook personal computer.

The heat pipes 21 are formed of, for example, a copper or aluminum alloy having a high heat conductivity. As shown in FIGS. 1 and 3, two heat pipes 21 extend through the substantially elliptical through hole 27 provided in the middle portion 25 of each radiation plate 20. Of course, the number of heat pipes 21 is not limited to two, and may be one, or three or more.

The heat pipes 21 and the radiation plates 20 are thermally and fixedly connected by, for example, brazing or caulking. The heat source is an IC as an example.

The distance F from leading ends of the first and second nozzles 6 and 7 in the jet generating mechanism 2 and the cutout ends 26 of the radiation plates 20 in the heat sink 3 is approximately 3 mm, for example, as shown in FIG. 1. Of course, the radiation plates 20 may be disposed directly at the leading ends of the nozzles. This can further reduce noise.

The jet generating mechanism 2 and the heat sink 3 are arranged so that the first and second nozzles 6 and 7 correspond to the spaces between the middle portions 25 that are provided between the bent side portions of the adjacent radiation plates 20, for example, as shown in FIG. 1.

The numbers of first and second nozzles 6 and 7 and radiation plates 20 are not limited to those shown in FIGS. 1 and 3.

### (Production Method for Cooling Device)

A production method for the cooling device 1 having the above-described configuration will be briefly described with emphasis on the heat sink 3.

FIG. 4 is a front view of a pressed flat plate that is not bent at both sides, and FIG. 5 is a perspective view showing a state in which the flat plate shown in FIG. 4 is bent at both sides by sheet metal working.

First, a thin plate formed of a heat conductive material, such as a copper alloy, is punched out into a desired shape by pressing, for example, as shown in FIG. 4. Simultaneously, a through hole 27 is formed so that heat pipes 21 can extend therethrough, and cutouts 24a and 24b having a length E (E in FIG. 4) of, for example, 4 mm from an end 26 are formed. Of course, these parts may be formed in different steps.

After that, the pressed flat plate is bent at both sides by sheet metal working, for example, as shown in FIG. 5. For example, the length C (C in FIG. 5) of bent side portions 23a and 23b from ends 22a and 22b is approximately 2 mm, and the length D (D in FIG. 5) in the Y-axis direction of a middle portion 25 between the bent side portions 23a and 23b is approximately 11 mm.

A plurality of produced radiation plates 20 are successively arranged so that the bent side portions 23a and 23b form one surface, and heat pipes 21 are inserted through the through holes 27, for example, as shown in FIG. 3.

Then, the radiation plates 20 are joined to the inserted heat pipes 21 by caulking, for example, as shown in FIG. 3. Of course, the method for joining the radiation plates 20 and the heat pipes 21 is not limited to caulking, and, the radiation plates 20 and the heat pipes 21 may be fixed, for example, by brazing.

The finished heat sink 3 is placed on a substrate (not shown) so that air discharged from the jet generating mechanism 2 is received by the cutout side of the heat sink 3, for example, as shown in FIG. 1. Then, other electronic circuits and a cover are attached, thus finishing the cooling device 1.

The above is the explanation of the production method for the cooling device 1.

In this way, according to this embodiment, the heat sink 3 includes the cutouts 24a and 24b that can take in outside air serving as gas. The cutouts 24a and 24b are provided on a side such as to receive air discharged from the first and second nozzles 6 and 7 serving as openings of the jet generating mechanism 2. Therefore, the pressure near the cutouts is decreased by the flow of air discharged from the first and second nozzles 6 and 7, and outside air is drawn in through the cutouts 24a and 24b. As a result, more gas than the gas discharged from the first and second nozzles 6 and 7 is discharged from an outlet of the heat sink. This can minimize the volume of jetted air to avoid noise, and can effectively radiate heat generated by the heat source.

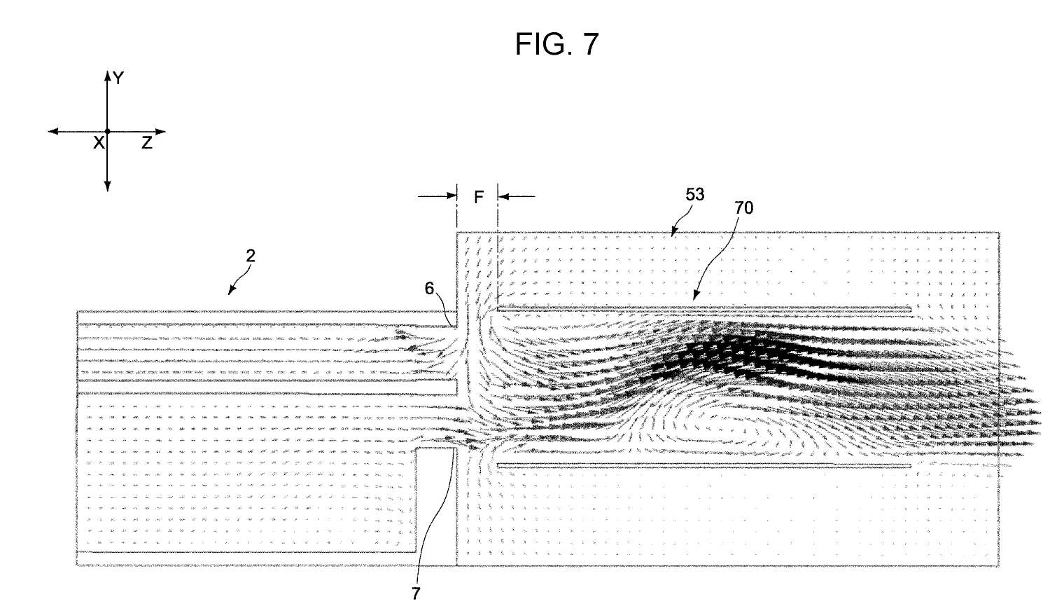

In a structure, for example, shown in FIG. 6 in which cutouts are not provided on sides of radiation plates 70 where gas discharged from the jet generating mechanism 2 is received, air flows, as shown in FIG. 7 (shown by the arrows in the figure). FIG. 6 is a perspective view of a heat sink 53 having no cutout, and FIG. 7 is a simulation view showing velocity vectors on the center cross-section of first and second nozzles when the heat sink 53 is combined with the jet generating mechanism 2. In the case shown in FIG. 7, the radiation plates 70 are placed at a distance of approximately 3 mm (F in FIG. 7) from the first and second nozzles 6 and 7 of the jet generating mechanism 2.

As a result of the simulation, in the above-described case in which the radiation plates 70 do not have a cutout, outside air flows in from between the first and second nozzles 6 and 7 and the radiation plates 70 (F in FIG. 7), although the amount of air is small.

The jet generating mechanism 2 using the vibrating plate 5 that periodically reciprocates has a characteristic that air discharged from the first and second nozzles 6 and 7 flows intermittently. For this reason, after air is discharged from the nozzles for a certain period, air is taken in from the same nozzle. In this case, outside air is drawn into the heat sink by the flow of discharged air. As a result, more air than the air discharged from the first and second nozzles 6 and 7 is discharged from the outlet of the heat sink.

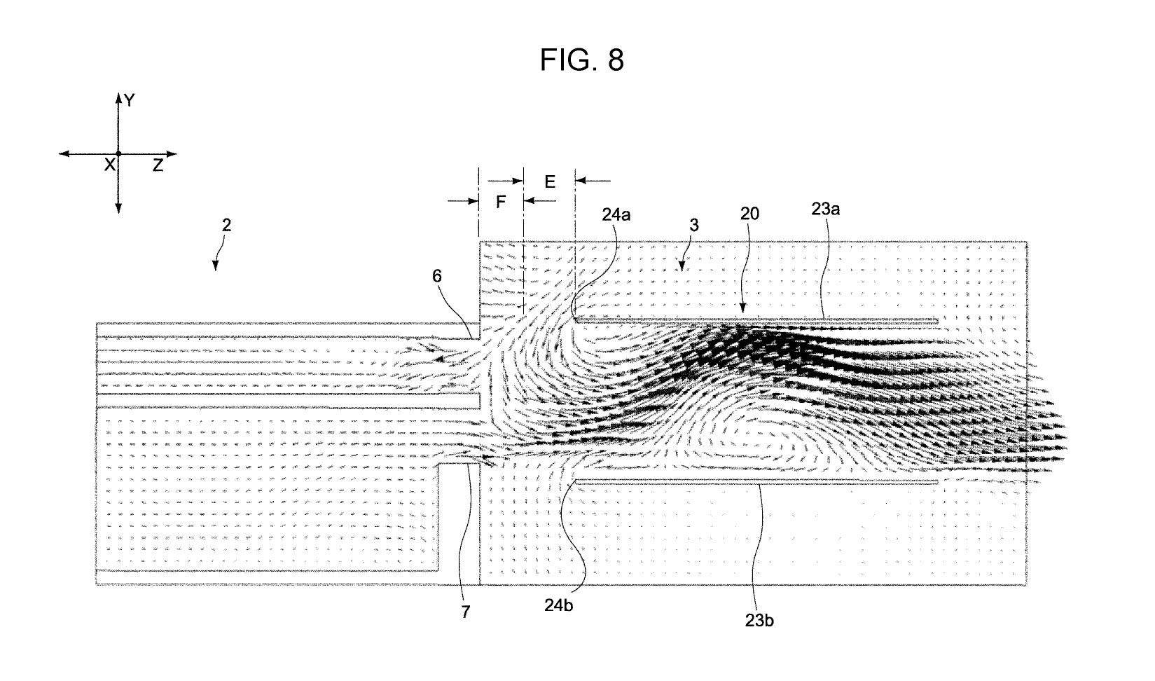

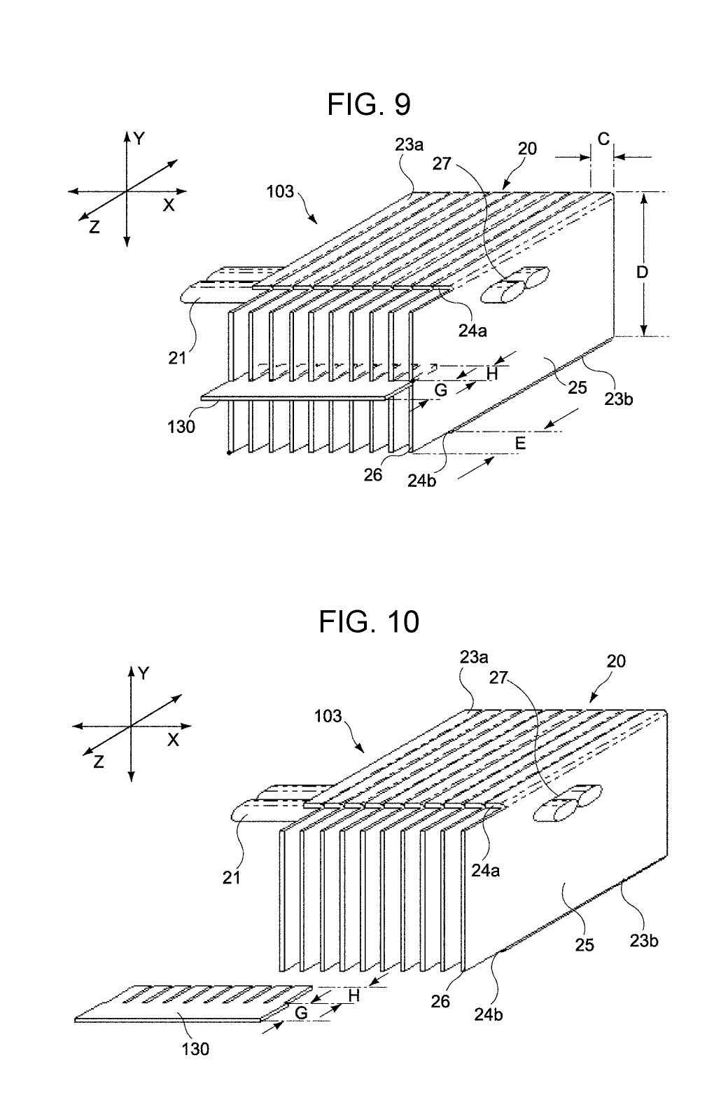

In contrast, when the radiation plates 20 have the cutouts 24a and 24b, air flows, as shown in FIG. 8 (shown by the arrows in the figure). FIG. 8 is a simulation view showing velocity vectors on the center cross section of the first and second nozzles when the heat sink 3 is combined with the jet generating mechanism 2.

As a result of the simulation, when the radiation plates 20 have the cutouts 24a and 24b, more gas flew in from the outside through the cutouts 24a and 24b than in the case in which the cutouts 24a and 24b are not provided, and the amount of air flow discharged from the outlet of the heat sink increased by a maximum of approximately 10%.

Moreover, since the amount of air flow discharged from the first and second nozzles 6 and 7 was not increased, flow noise depending on the maximum amount of air flow discharged from the first and second nozzles 6 and 7 was not increased by increasing the amount of air flow discharged from the nozzles. Consequently, noise was reduced, and heat generated by the heat source was radiated effectively.

Further, since there is no need to decrease the nozzle cross-sectional area, pressure loss in the nozzles did not increase, and power consumption of the jet generating mechanism 2 did not increase. The above is the explanation of the simulation result.

The cutouts 24a and 24b that can take in outside gas are provided on the side of the heat sink 3 where gas discharged from the jet generating mechanism 2 is received. Therefore, formation is easy, and the production cost can be reduced. Moreover, outside air can be taken in more smoothly.

The heat sink 3 includes a plurality of radiation plates 20 that receive discharged gas. The radiation plates 20 are each formed of a flat plate bent at both sides, and are arranged successively. The cutouts 24a and 24b are provided in the bent side portions 23a and 23b. Therefore, a heat sink 3 having high radiation effect can be easily produced by arranging a plurality of radiation plates 20. This can reduce the production cost.

For example, when a plurality of radiation plates 20 are successively arranged in a manner such that the bent side portions 23a and 23b are aligned to form an upper surface and a lower surface, the bent side faces face outside the heat sink 3. By forming the cutouts 24a and 24b in the bent side portions 23a and 23b, outside gas can be taken in easily.

### Second Embodiment

FIG. 9 is a perspective view of a heat sink according to a second embodiment of the present invention.

This embodiment is different from the first embodiment in that a partition plate is attached to radiation plates of the heat sink. Therefore, the following description will center on this difference.

A heat sink 103 includes a plurality of radiation plates 20 that receive air serving as gas discharged from a jet generating mechanism 2, heat pipes 21 serving as a heat conductive member that transmits heat from a heat source to the radiation plates 20, and a partition plate 130 provided at the midpoint between first and second nozzles 6 and 7, for example, as shown in FIG. 9.

The partition plate 130 is provided on sides of the radiation plates 20 where gas discharged from the jet generating mechanism 2 is received, and between the first and second nozzles 6 and 7 of the jet generating mechanism 2. The partition plate 130 extends in a direction substantially orthogonal to straight lines that connect the first and second nozzles 6 and 7.

The partition plate 130 also extends substantially orthogonal to a direction that connects bent side portions 23a and 23b of the radiation plates 20 (Y-axis direction in FIG. 9), and has a predetermined length G (G in FIG. 9) from ends 26 of the radiation plates 20 toward the jet generating mechanism 2, for example, as shown in FIG. 9. Further, the partition plate 130 extends by a predetermined length H (H in FIG. 9) from the ends 26 toward the interior of the heat sink 103.

That is, the partition plate 130 at least overlaps with cutouts 24a and 24b on an X-Z plane. This can reduce gas flowing into the cutouts 24a and 24b. For example, both predetermined lengths G and H are approximately 2 mm. The partition plate 130 overlaps with the cutouts 24a and 24b by the length H in plan view.

Further, the partition plate 130 extends between the first nozzles 6 and the second nozzles 7, and a part thereof is fitted on the ends 26 of the radiation plates 20. That is, the partition plate 130 protrudes by the predetermined length G from the ends 26 of the radiation plates 20 toward the jet generating mechanism 2, and extends by the predetermined length H from the ends 26 into the heat sink 103.

The partition plate 130 is substantially parallel to the faces of the bent side portions 23a and 23b of the radiation plates 20. While a single partition plate 130 is provided for a plurality of radiation plates 20, for example, as shown in FIG. 9, it may be provided for each radiation plate 20.

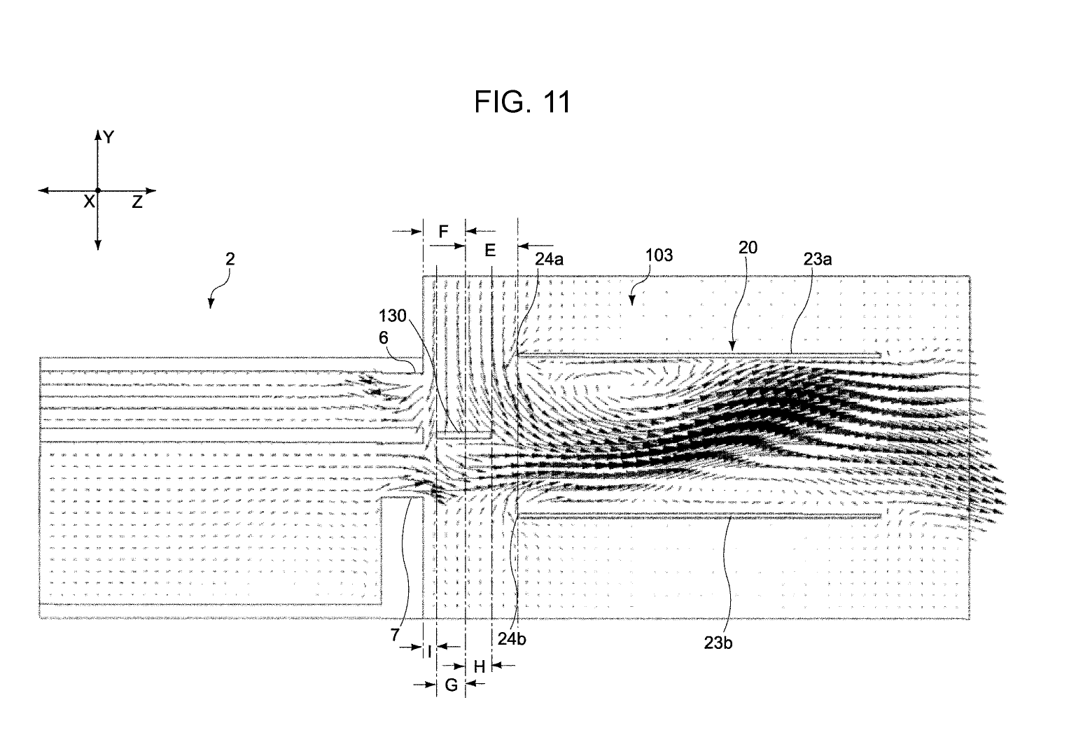

While the distance I between the leading ends of the first and second nozzles 6 and 7 of the jet generating mechanism 2 and the end of the partition plate 130 of the heat sink 130 close to the jet generating mechanism is, for example, approximately 1 mm, as shown in FIG. 11, the partition plate 130 may be disposed directly at the leading ends of the nozzles. This can further reduce noise.

FIG. 10 is a perspective view showing a state in which the partition plate is attached to the radiation plates.

A production method for the cooling device having the above-described configuration is different from the first embodiment in that the partition plate 130 is provided in the heat sink. Therefore, the following description will center on this difference.

First, a thin plate formed of a heat conductive material, such as a copper alloy, is punched out in a desired comb shape by pressing, for example, as shown in FIG. 10. For example, punching is performed so that the length of teeth is equal to the predetermined length H of the portions of the radiation plates 20 extending from the ends 26 to the interior of the heat sink 103, that is, 2 mm.

Subsequently, a partition plate 130 worked in a comb shape is fitted on the ends 26 of the radiation plates 20, and the radiation plates 20 and the partition plate 130 are partly fixed, for example, by brazing, as shown in FIG. 9.

The finished heat sink 103 is placed on a substrate (not shown) so that air discharged from the jet generating mechanism 2 is received by the side of the heat sink 130 where the cutouts 24a and 24b and the partition plate 130 are provided. Then, other electronic circuits and a cover are attached, thus finishing the cooling device.

The above is the explanation of the production method for the cooling device.

In this way, according to this embodiment, the partition plate 130 is provided on the gas receiving sides of the radiation plates 20 and between the first nozzles 6 and the second nozzles 7 of the jet generating mechanism 2. The partition plate 130 extends in a direction substantially orthogonal to the straight lines that connect the first and second nozzles 6 and 7. Therefore, for example, the gas flow discharged from the first nozzles 6 can be restrained from turning toward the second nozzles 7, and the amount of gas flowing out of the heat sink through the cutouts 24a and 24b can be reduced. This allows more outside gas to be taken in from the cutouts 24a and 24b and allows gas to flow to the outlet of the heat sink.

For example, according to the simulation result of the first embodiment shown in FIG. 8, when the cutouts 24a and 24b were provided in the radiation plates 20, more outside gas could be taken in than in the case shown in FIG. 7 in which the cutouts 24a and 24b were not provided.

However, in the jet generating mechanism 2 using the vibrating plate that periodically reciprocates, for example, air flow discharged from the second nozzles 7 turned toward the first nozzles 6 that performed air intake. When the cutouts 24a and 24b were provided on the sides of the radiation plates 20 where the discharged air was received, the degree of turning increased. When the cutouts were too large, the amount of turning air that came out of the heat sink increased.

Accordingly, when the partition plate 130 was provided between the first and second nozzles 6 and 7 of the jet generating mechanism 2 in order to decrease the degree of turning of air flow discharged from the nozzles, as in this embodiment, the air flew, as shown in FIG. 11 (shown by the arrows in the figure). FIG. 11 is a simulation view showing velocity vectors on the center cross section of the first and second nozzles when the heat sink 103 is combined with the jet generating mechanism 2.

According to the simulation result shown in FIG. 11, the amount of flow at the outlet of the heat sink 103 increased by 10 to 30%, when compared with the case in which the heat sink 53 having no cutout and no partition plate shown in FIG. 6 was combined with the jet generating mechanism. As a result, the amount of flow at the outlet of the heat sink 103 became about double the volume of air discharged from the first and second nozzles 6 and 7 of the jet generating mechanism 2.

That is, when the partition plate 130 was attached to the radiation plates 20 between the first and second nozzles 6 and 7 of the jet generating mechanism 2, even if the size of the cutouts of the radiation plates 20 was increased, the amount of air, which was discharged from the first and second nozzles 6 and 7 and flew out of the heat sink through the cutouts, could be made smaller than when the partition plate 130 was not provided.

As a result, it was possible to take in more air through the cutouts and to cause more air to flow to the outlet of the heat sink. The above is the explanation of the simulation result.

By combining the heat sink 103 according to the present invention with the jet generating mechanism 2, the amount of air flow at the outlet of the heat sink can be increased without increasing the amount of air flow discharged from the nozzles. For this reason, thermal resistance can be reduced without increasing flow noise that is substantially determined by the maximum amount of air flow discharged from the nozzles.

The radiation plates 20 are each formed of a flat plate bent at both sides. The partition plate 130 extends between the first nozzles 6 and the second nozzles 7, and is partly fitted on the middle portions 25 between both bent side portions of the radiation plates 20. Therefore, for example, even when air intake and air discharge are alternately repeated by the first nozzles 6 and the second nozzles 7, it is possible to reduce the amount of gas flow which is discharged from one of the first and second nozzles 7 and turns toward the other nozzle that performs air intake.

Since the partition plate 130 is partly fitted on the middle portions 25 between both side portions of the radiation plates 20 each of which is formed of a flat plate bent at both sides, the partition plate 130 is easily attached to the radiation plates 20, and the attachment strength can be increased.

The partition plate 130 at least overlaps with the cutouts 24a and 24b in plan view. Since gas that is going to flow toward the cutouts 24a and 24b is regulated by the partition plate 130, for example, the amount of gas turning toward the first nozzles 6 that perform air intake can be further reduced, and the amount of gas flowing out of the heat sink through the cutouts 24a and 24b can be reduced further.

### Third Embodiment

FIG. 12 is a perspective view of a heat sink according to a third embodiment.

This embodiment is different from the first embodiment in that heat pipes of the heat sink do not extend through radiation plates, but are provided on faces of bent side portions 23a or 23b of the radiation plates. Therefore, the following description will center on this difference.

A heat sink 203 includes a plurality of radiation plates 20 that receive air serving as gas discharged from a jet generating mechanism 2, heat pipes 221 serving as a heat conductive member that transmits heat from a heat source to the radiation plates 20, and a partition plate 130 provided between first and second nozzles 6 and 7, for example, as shown in FIG. 12.

The heat pipes 221 are partly brazed and thermally connected to the faces of the bent side portions 23a of the radiation plates 20, for example, as shown in FIG. 12.

Since the heat pipes 221 are substantially elliptical in cross section, the contact area between the heat pipes 221 and the faces of the bent side portions 23a of the radiation plates 20 is increased. This allows heat to be more efficiently exchanged between the heat pipes 221 and the radiation plates 20. Of course, the number of the heat pipes is not limited to two, similarly to the first embodiment.

A production method for the cooling device having the above-described configuration is substantially similar to that adopted in the first embodiment except that the heat pipes 221 do not extend through a plurality of radiation plates 20, but, for example, are partly brazed to the bent side portions 23a after the radiation plates are arranged successively. Therefore, a description of the production method is omitted.

In this way, according to this embodiment, since there is no need to form a through hole in each radiation plate 20, the surface area of the radiation plate 20 can be prevented from decreasing, and cooling efficiency can be enhanced further.

Further, when compared with the case in which the heat pipes are inserted and fixed in the through holes 27 of the radiation plates 20, the contact area can be easily ensured, cooling efficiency can be enhanced, and easier joint is possible.

### Fourth Embodiment

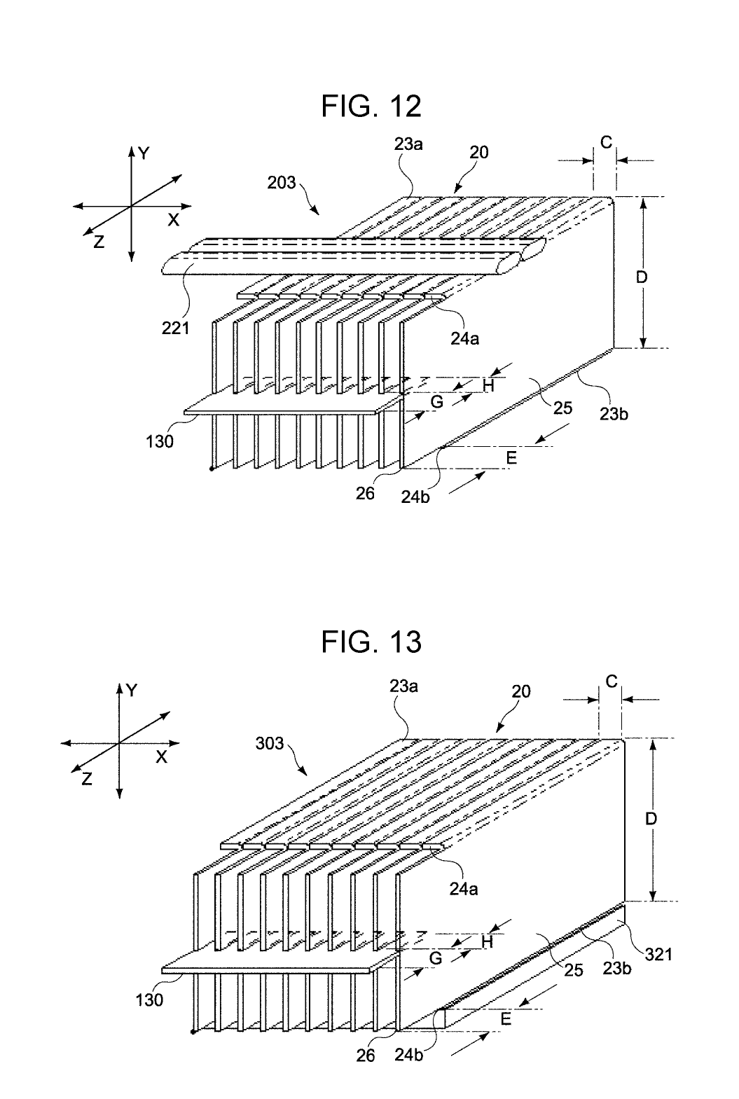

FIG. 13 is a perspective view of a heat sink according to a fourth embodiment.

This embodiment is different from the first embodiment in that heat pipes are not provided in a heat sink, and a plate is provided as a heat conductive member instead. Therefore, the following description will center on this difference.

A heat sink 303 includes a plurality of radiation plates 20 that receive air serving as gas discharged from a jet generating mechanism 2, a plate 321 serving as a heat conductive member that transmits heat from a heat source to the radiation plates 20, and a partition plate 130 provided between first and second nozzles 6 and 7, for example, as shown in FIG. 13.

The plate 321 is partly brazed and thermally connected to faces of bent side portions 23b of the radiation plates 20, for example, as shown in FIG. 13.

Since the plate 321 is substantially rectangular, for example, as shown in FIG. 13, the contact area of the plate 321 with the faces of the aligned bent side portions 23b is increased, and heat exchange can be more efficiently performed between the plate 321 and the radiation plates 20. The plate is formed of, for example, a copper or aluminum alloy having high heat conductivity.

For example, the heat source is thermally connected to the plate 321 serving as the heat conductive member.

A production method for the cooling device having the above-described configuration is substantially similar to that adopted in the first embodiment except that heat pipes are not provided and the plate 321 serving as the heat conductive member is provided instead on the faces of the bent side portions 23b. Therefore, a description of the production method is omitted.

In this way, according to this embodiment, since the heat source can be thermally connected to the radiation plates 20 more directly via the plate 321 serving as the heat conductive member, cooling efficiency can be enhanced further.

In addition, when compared with the case in which the heat pipes are inserted and fixed in the through holes 27 of the radiation plates 20, the contact area can be easily ensured, cooling efficiency can be enhanced, joint is easier, and the production cost can be reduced.

### Fifth Embodiment

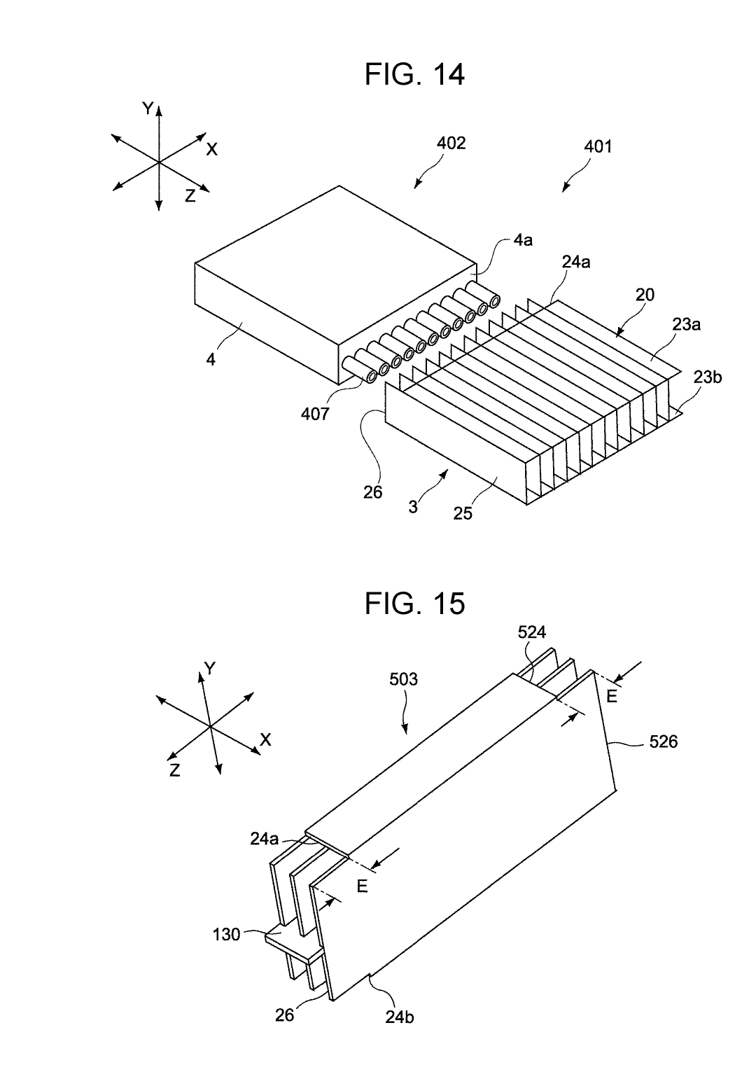

FIG. 14 is a perspective view of a cooling device according to a fifth embodiment.

This embodiment is different from the first embodiment in that only first or second nozzles are provided as openings in a jet generating mechanism 2. Therefore, the following description will center on this difference.

A cooling device 401 includes, for example, a jet generating mechanism 402 that discharges a pulsating flow of gas, and a heat sink 3 that receives the gas discharged from the jet generating mechanism 402.

The jet generating mechanism 402 includes, for example, a housing 4 containing gas, and a vibrating plate 5 serving as a vibrating body vibratably mounted in the housing.

On one side face 4a of the housing 4, a plurality of nozzles 407 are arranged in the lateral direction (X-axis direction in FIG. 14) as openings that discharge air serving as gas in a chamber, which will be described below, toward the heat sink 3 opposing the side face, for example, as shown in FIG. 14. The nozzles 407 may be provided integrally with the housing 4.

For example, the vibrating plate 5 is supported on an inner wall of the housing 4 by an elastic support member 17, and a chamber is defined by the vibrating plate 5, the elastic support member 17, and the housing 4.

Operation of the jet generating mechanism 402 having the above-described configuration will be described briefly. When the vibrating plate 5 is displaced in a direction such as to increase the volume of the chamber, the pressure in the chamber decreases. Thereby, air flows from the outside of the housing 4 into the chamber through the nozzles 407. Conversely, when the vibrating plate 5 is displaced in a direction such as to decrease the volume of the chamber, the pressure in the chamber increases. Air in the chamber is thereby discharged outside through the nozzles 407, and the air is blown against the heat sink 3. Consequently, the heat sink 3 is cooled.

Of course, the numbers of nozzles 407 and radiation plates 20 are not limited to those shown in FIG. 14.

A production method for the cooling device having the above-described configuration is substantially similar to that adopted in the first embodiment except that only first or second nozzles are provided as the openings of the jet generating mechanism 2. Therefore, a description of the production method is omitted.

In this way, according to this embodiment, since only the first or second nozzles are provided in the jet generating mechanism 402, the number of components is reduced. This can reduce the production cost.

### Sixth Embodiment

FIG. 15 is a perspective view of a heat sink according to a sixth embodiment.

A heat sink 503 includes cutouts 24a and 24b, and also includes a cutout 524 serving as a second vent portion on a side opposite an air receiving side, for example, as shown in FIG. 15. On the opposite side, air flows out of the heat sink 503.

For example, the cutout 524 is formed similarly to the cutout 24a. More specifically, as shown in FIG. 15, a substantially rectangular portion parallel to a partition surface of a partition plate 130 is cut out. The cutout extends inward by a predetermined length E (E in FIG. 15) from an end 526 on an outlet side for discharged air. While the length E is, for example, 4 mm, it is not limited thereto.

Since a production method for a cooling device including the heat sink 503 is substantially similar to that adopted in the second embodiment except that the cutout 524 is provided, a description thereof is omitted.

While the cutout 524 is provided on the same side (upper side in FIG. 15) as that of the cutout 24a, of the cutouts 24a and 24b, but is not provided on the same side (lower side in FIG. 15) as that of the cutout 24b in FIG. 15, it may be provided on each side or only on the same side as that of the cutout 24b.

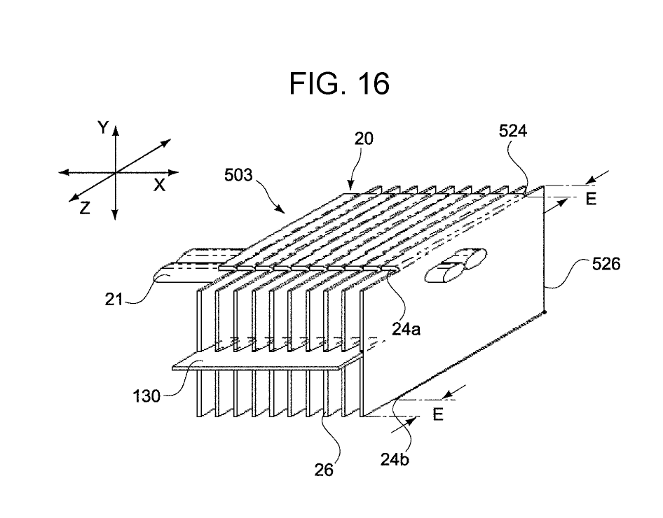

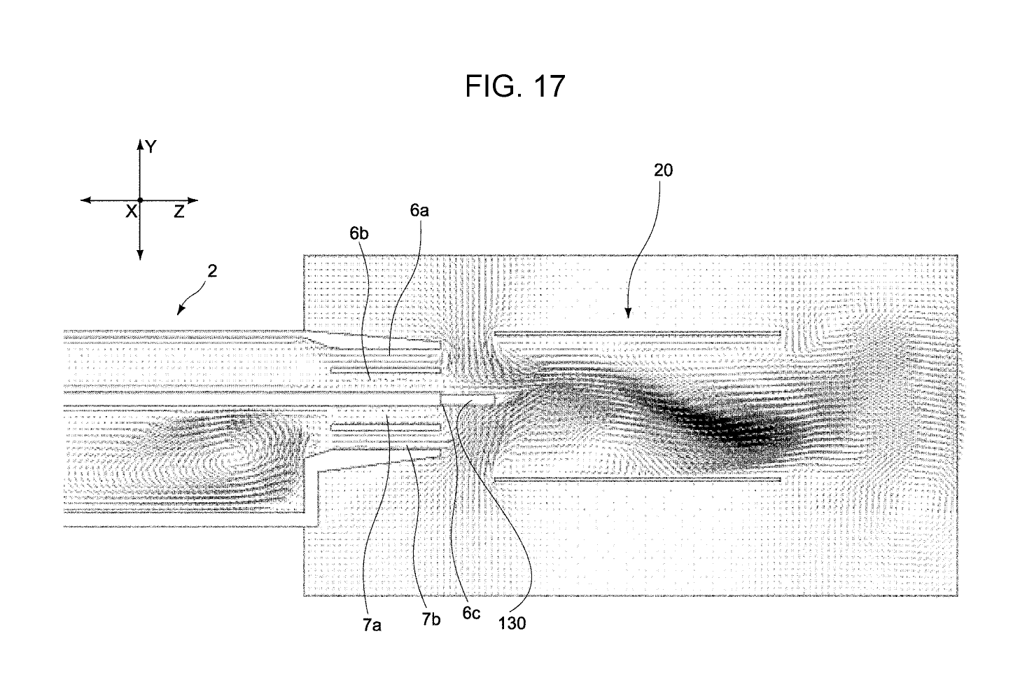

Radiation plates and heat pipes serving as heat conductive members in the heat sink 503 are formed, for example, similarly to those adopted in the second embodiment, as shown in FIG. 16. Of course, the numbers of radiation plates 20 and so on are not limited to those shown in FIG. 16.

In this way, according to this embodiment, the heat sink 503 has the cutout 524 on the side opposite the gas receiving side. Therefore, pressure loss is decreased at the opposite outlet for inflow gas, and the amount of gas flowing out of the heat sink 503 can be increased. Since an increase in radiation efficiency due to the increase in amount of gas flow is larger than a decrease in radiation efficiency due to formation of the cutout, the radiation efficiency can be increased as a whole.

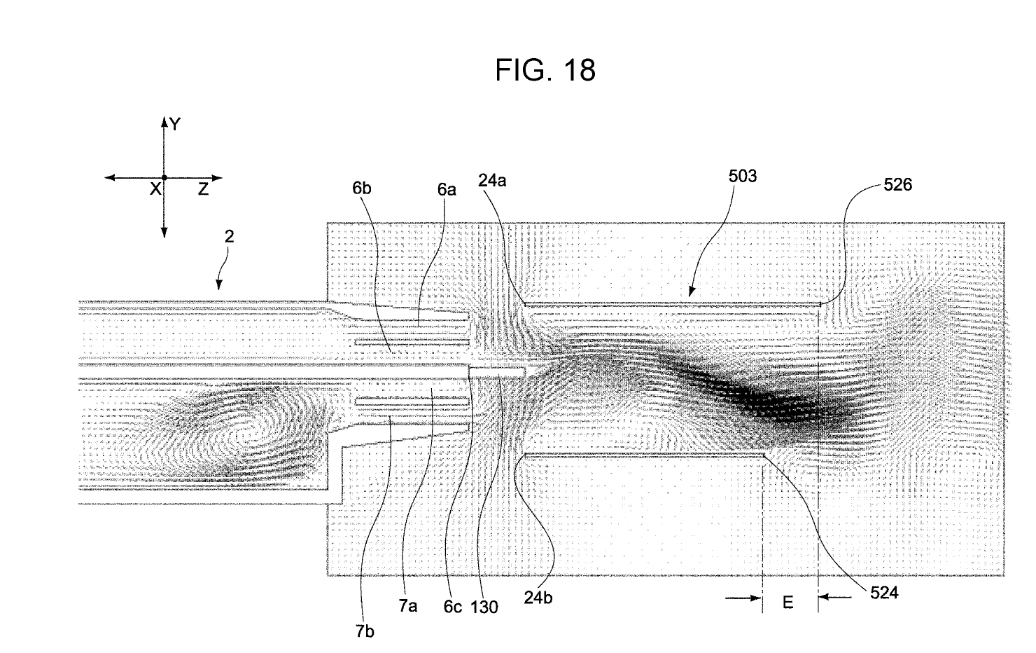

A consideration will be taken of the amount of flow in a heat sink including nozzles 6a and 6b and nozzles 7a and 7b through which gas is discharged from a housing 4 of a jet generating mechanism 2, for example, as shown in FIGS. 17 and 18. Channels of the nozzles 6a and 6b communicate with a first chamber 18, and the nozzles 6a and 6b are arranged vertically (Y-axis direction), as shown in FIG. 17. Further, a plurality of nozzles 6a and a plurality of nozzles 6b are arranged in a direction (X-axis direction in FIG. 17) orthogonal to the vertical direction. Channels of the nozzles 7a and 7b communicate with a second chamber 19, and a plurality of nozzles 7a and a plurality of nozzles 7b are provided similarly to the nozzles 6a and 6b. A partition plate 130 is provided on a heat-sink-side end face 6c between the nozzles 6b and 7a.

FIG. 17 is a simulation view showing velocity vectors on the center nozzle cross section when the cutout 524 is not provided. FIG. 18 is a simulation view showing velocity vectors on the center nozzle cross section when the cutout 524 is provided on a lower side (air flows are shown by the arrows in the figures).

When the same volume of air is discharged from the nozzles in both cases, the amount of flow at the outlet of the heat sink increased by 10 to 30% in the case shown in FIG. 17, when compared with the case in which the cutouts 24a and 24b were not provided.

When the cutout 524 was also provided on the opposite flow-out side, as shown in FIG. 18, the amount of flow at the outlet of the heat sink further increased by 3 to 5% from that in the case shown in FIG. 17. As a result, the amount of flow at the outlet of the heat sink became double or more than the volume of air discharged from the nozzles. While the amount of flow is large near the outlet of the heat sink, for example, as shown in FIG. 18 (a dense portion in the figure), the dense portion extends more widely than in FIG. 17. This shows that the amount of flow increased near the outlet.

That is, pressure loss at the outlet is decreased by adding the cutout on the flow-out side of the heat sink, and the amount of gas flowing out of the heat sink 503 can be thereby increased. The above is the explanation of the simulation result.

From the above, by combining the heat sink 503 with the jet generating mechanism 2, the amount of air flow at the outlet of the heat sink can be increased without increasing the amount of air flow discharged from the nozzles 6a and 6b and the nozzles 7a and 7b. For this reason, thermal resistance can be reduced without increasing flow noise that is substantially determined by the maximum flow velocity of air discharged from the nozzles.

### Seventh Embodiment

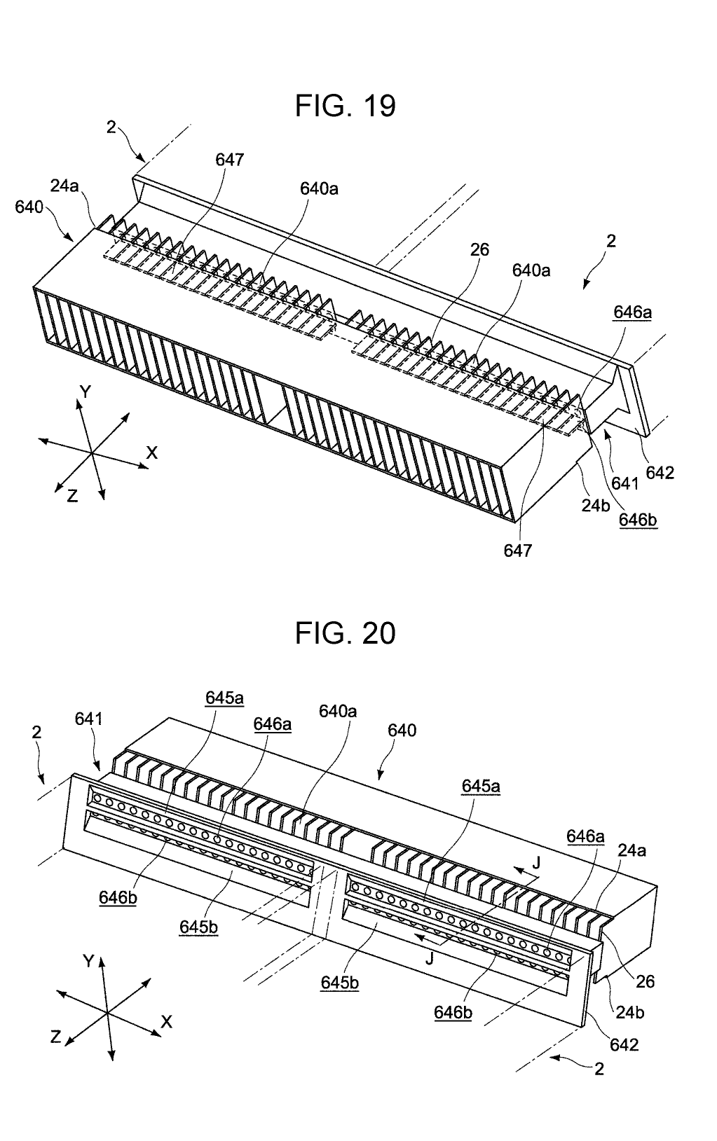

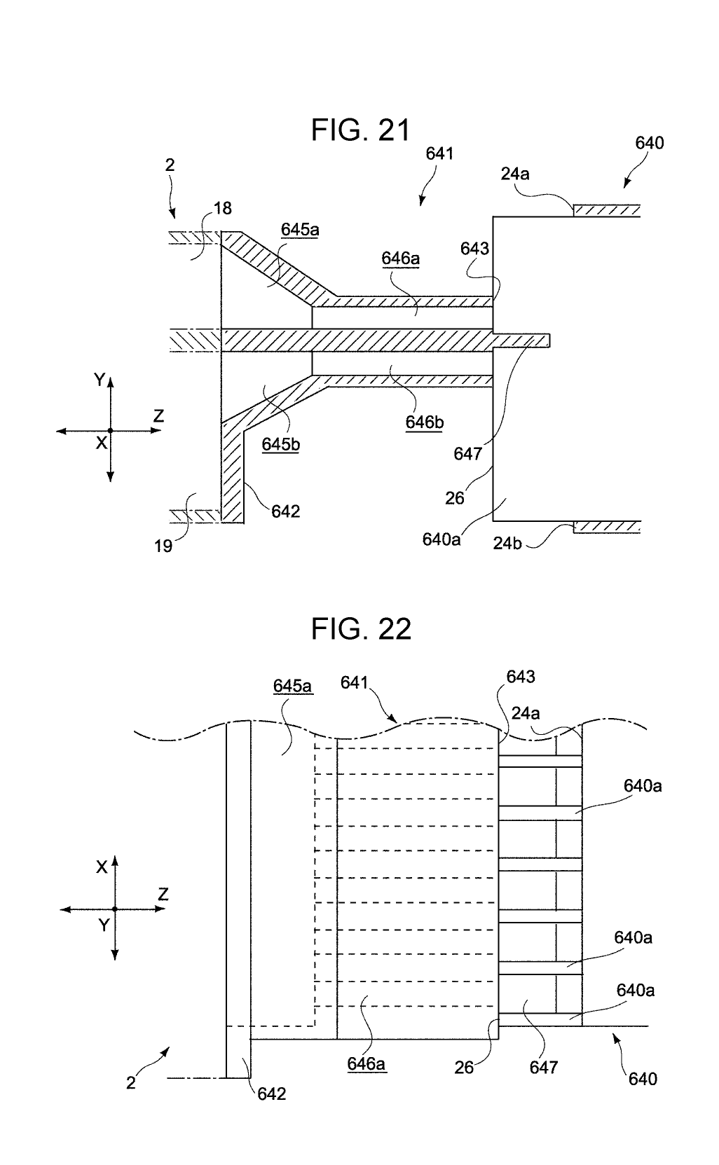

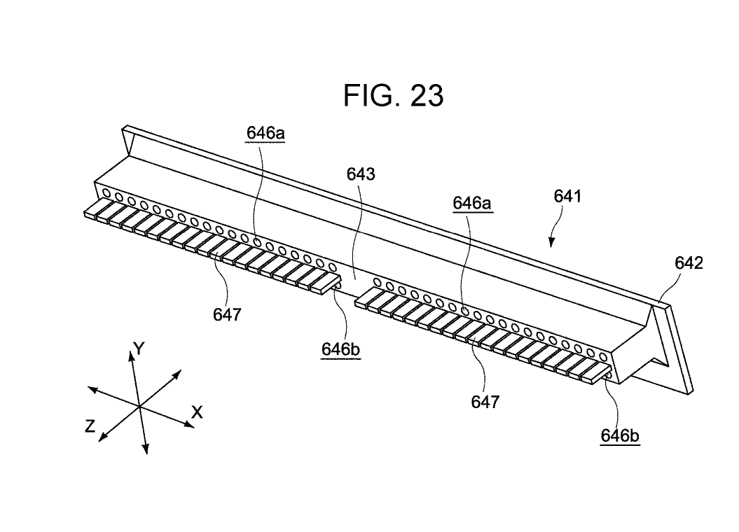

FIG. 19 is a partial perspective view of a cooling device according to a seventh embodiment, FIG. 20 is a partial perspective view of the cooling device, as viewed in a direction opposite to that in FIG. 19, FIG. 21 is a cross-sectional view, taken along line J-J in FIG. 20, FIG. 22 is a partial plan view of the portion shown in FIG. 20, and FIG. 23 is a perspective view of a nozzle unit shown in FIG. 19.

A heat sink unit 640 and a nozzle unit 641 are integrally molded, for example, as shown in FIG. 19. The heat sink unit 640 and the nozzle unit 641 can be integrally molded, for example, with a die. As shown in FIGS. 20 and 21, the nozzle unit 641 has a base plate 642. The nozzle unit 641 also includes gas channels 645a and 645b that respectively communicate with first and second chambers 18 and 19 provided in a jet generating mechanism 2, for example, as shown in FIG. 21. The channels 645a and 645b extend in the X-direction, as shown in FIG. 21. The channels 645a and 645b gradually tapered off toward the heat sink unit 640. This makes air flow smooth, and achieves silence.

As shown in FIG. 22, the channel 645 branches into a plurality of channels 646a, and each channel 646a communicates with a space between fins 640a provided in the heat sink unit 640. Similarly, the channel 645b branches into a plurality of channels 646b, and each channel 646b communicates with a space between the fins 640a in the heat sink unit 640.

Further, a heat-sink-side end face 643 of the nozzle unit 641 is integrally connected to ends 26 of the fins 640a so that the channels 646a and 646b communicate with the spaces between the fins 640a, as shown in FIGS. 21 and 22.

The end face 643 of the nozzle unit 641 is also integrally connected to partition plates 647 that are disposed between the channels 646a and 646b arranged in the vertical direction, for example, as shown in FIG. 23. A plurality of partition plates 647 are integrally connected to the end face 643 so as to be disposed between a plurality of channels 646a and 646b arranged in the lateral direction (X-axis direction in FIG. 23), for example, as shown in FIG. 23.

Similarly to the first embodiment, the heat sink unit 640 includes cutouts 24a and 24b shown in FIGS. 21 and 22.

Two jet generating mechanism 2, each including the first and second chambers 18 and 19 and excluding the nozzle unit, are juxtaposed and connected to the base plate 642 of the nozzle unit 641, as shown in FIGS. 19 and 20. Alternatively, the single jet generating mechanism 2 may be disposed so that air is discharged from all channels 646a and 646b by the jet generating mechanism 2.

While the partition plates 647 are separately provided corresponding to the channels 646a and 646b in the above description, they may be replaced by a single comb-shaped partition plate, similarly to the partition plate 130 shown in FIG. 10.

While the heat sink unit 640 has the cutouts 24a and 24b in the above description, for example, the cutouts 24a and 24b may be omitted from the heat sink unit. Of course, the numbers of channels 646a and 646b, fins, and partition plates are not limited to those shown in FIG. 19.

A production method for the cooling device including the heat sink unit 640 and the nozzle unit 641 is substantially similar to that adopted in the first embodiment except that the heat sink unit 640 and the nozzle unit 641 are molded integrally.

For example, the heat sink unit 640, the nozzle unit 641, and the partition plates 647 are integrally molded with a die, and a heat conductive member, such as a heat pipe 21, is then attached to the heat sink unit 640. Further, the jet generating mechanism 2 having no nozzle unit is mounted on the base plate 642 of the nozzle unit 641, thus finishing the cooling device.

The heat conductive material used for the heat sink unit 640 is not limited to a moldable magnesium alloy, and it is satisfactory as long as the material is castable. For example, an aluminum alloy can also be used. While not only the heat pipe 21, but also a copper alloy, an aluminum alloy, or a vapor chamber as a kind of heat pipe is frequently used as the heat conductive member for transmitting heat from the heat source to the heat sink unit 640, for example, a heat transport device utilizing liquid can be used. However, when a magnesium alloy and a copper material are used, it is necessary to plate at least one of the materials with nickel for corrosion prevention.

In this way, according to this embodiment, the heat sink unit 640 and the nozzle unit 641 of the jet generating mechanism 2 are formed by integral molding. Therefore, the pressing and metal sheet working steps of a plurality of radiation plates can be replaced with one molding step. This reduces the production cost, and allows the cooling device to be produced with high precision.

When the heat pipe serving as the heat conductive member is attached to the heat sink unit 640, the fins 640a do not need to be fixed with a jig, and brazing can be performed more easily.

While the present invention has been described with reference to the preferred embodiments, it is not limited to any of the above-described embodiments. The present invention can be carried out by appropriately making modifications within the technical scope of the present invention or by combining the above-described embodiments.

For example, while the partition plate 130 is provided in the heat sink 103 in the above-described embodiments, it can be provided integrally with the nozzles of the jet generating mechanism.

1. A cooling device comprising:
a jet generating mechanism including a housing having an opening and containing gas, and a vibrating body vibratably mounted in the housing and configured to vibrate to discharge the gas as a pulsating flow through the opening; and
a heat sink including a first vent portion through which outside gas can be taken in, the first vent portion being provided on a gas receiving side of the heat sink where the gas discharged from the opening is received.

2. The cooling device according to claim 1, wherein the heat sink further includes a radiation plate configured to receive the discharged gas, and the first vent portion is a cutout provided on a side of the radiation plate such as to receive the gas.

3. The cooling device according to claim 1,
wherein the jet generating mechanism further includes a first chamber and a second chamber provided in the housing such that the vibrating body is disposed therebetween, and the opening includes a first opening communicating with the first chamber, and a second opening communicating with the second chamber, and
wherein the heat sink further includes a radiation plate configured to receive the discharged gas, and a partition plate provided on a side of the radiation plate such as to receive the gas and between the first opening and the second opening, the partition plate extending in a direction substantially orthogonal to a straight line that connects the first and second openings.

4. The cooling device according to claim 1,
wherein the heat sink further includes a radiation plate configured to receive the discharged gas, the radiation plate is formed of a flat plate bent at both sides, and includes a plurality of radiation plates arranged successively, and
wherein the first vent portion is provided on the bent sides.

5. The cooling device according to claim 3,
wherein the radiation plate is formed of a flat plate bent at both sides, and
wherein the partition plate extends about at the midpoint between the first opening and the second opening, and is inserted in a middle portion between both bent sides of the radiation plate.

6. The cooling device according to claim 3, wherein the partition plate at least overlaps with the first vent portion in plan view.

7. The cooling device according to claim 1, wherein the heat sink further includes a second vent portion provided on a side opposite the gas receiving side.

8. The cooling device according to claim 7, wherein the heat sink further includes a radiation plate configured to receive the discharged gas, and the second vent portion is a cutout provided on the opposite side of the radiation plate.

9. A heat sink that receives a pulsating flow of gas via first and second openings of a jet generating mechanism,
wherein the jet generating mechanism includes:
a housing having the first and second openings and containing gas; and
a vibrating body vibratably mounted in the housing and configured to vibrate to discharge the pulsating flow of gas via the first and second openings, and
wherein the heat sink includes:
a radiation plate having a first vent portion through which outside gas can be taken in, the first vent portion being provided on a gas receiving side where the gas is received; and
a partition plate provided on the gas receiving side of the radiation plate and between the first opening and the second opening, the partition plate extending in a direction substantially orthogonal to a straight line that connects the first and second openings.

10. The heat sink according to claim 9, wherein the first vent portion is a cutout provided on the gas receiving side of the radiation plate.

11. The heat sink according to claim 9, wherein the radiation plate further includes a second vent portion provided on a side opposite the gas receiving side.

12. The heat sink according to claim 11, wherein the second vent portion is a cutout provided on the opposite side of the radiation plate.

13. An electronic apparatus comprising:
a heat source;
a jet generating mechanism including a housing having an opening and containing gas, and a vibrating body vibratably mounted in the housing and configured to vibrate to discharge the gas as a pulsating flow from the opening; and
a heat sink including a radiation plate having a vent portion through which outside gas can be taken in, the vent portion being provided on a side where the gas discharged from the opening is received, and
wherein the heat sink is thermally connected to the heat source.
